(19) United States
(12) Patent Application Publication
(10) Pub. No.: US 2023/0386794 A1
(43) Pub. Date: Nov. 30, 2023

(54) SUBSTRATE PROCESSING METHOD AND SUBSTRATE PROCESSING APPARATUS

(71) Applicant: Tokyo Electron Limited, Tokyo (JP)

(72) Inventors: Satoru NAKAMURA, Miyagi (JP); Shinya MORIKITA, Miyagi (JP); Fumiya TANIFUJI, Miyagi (JP)

(73) Assignee: Tokyo Electron Limited, Tokyo (JP)

(21) Appl. No.: 18/231,278

(22) Filed: Aug. 8, 2023

Related U.S. Application Data
(62) Division of application No. 17/194,840, filed on Mar. 8, 2021.

(30) Foreign Application Priority Data
Mar. 18, 2020 (JP) 2020-047262

(51) Int. Cl. H01J 37/32; H01L 21/67; H01L 21/3065; H01L 21/311

(52) U.S. Cl. CPC H01J 37/3244; H01J 37/32715; H01L 21/67069; H01L 21/3065; H01L 21/31116; H01J 2237/334

(57) ABSTRACT

A substrate processing method is a substrate processing method for a substrate processing apparatus. The method includes: a) supplying a process gas containing fluorocarbon and a rare gas to a processing container in which a placing pedestal for placing a processing target object including a first region made of silicon oxide is arranged; b) plasma-processing the processing target object by a first plasma of the process gas generated under a first plasma generation condition; c) plasma-processing the processing target object in which a bias potential is generated on the processing target object by a second plasma of the process gas generated under a second plasma generation condition different from the first plasma generation condition; and d) repeating the b) and the c).

### CROSS-REFERENCE TO RELATED APPLICATIONS

The present application is a divisional application of U.S. application Ser. No. 17/194,840 filed on Mar. 8, 2021, which claims priority to and incorporates by reference the entire contents of Japanese Patent Application No. 2020-047262 filed in Japan on Mar. 18, 2020.

### FIELD

The present disclosure relates to a substrate processing method and a substrate processing apparatus.

### BACKGROUND

As the miniaturization of semiconductors progresses, compatibility between an etching selection ratio and suppression (removability) of etching defects in a narrow space is desired for a dry etching process. On the other hand, a method called ALE (Atomic Layer Etching) is proposed in which etching is promoted by repeating an etchant deposition step and an ion irradiation step. In the ALE, each step is separated by switching a process gas used in the deposition step and the ion irradiation step.
Patent Literature 1: Japanese Laid-open Patent Publication No. 2015-173240
Patent Literature 2: Japanese Laid-open Patent Publication No. 2016-136616

The present disclosure provides a substrate processing method and a substrate processing apparatus capable of performing etching at a higher speed and a higher selection ratio than a gas switching method.

### SUMMARY

According to an aspect of a present disclosure, a substrate processing method for a substrate processing apparatus, the method includes: a) supplying a process gas containing fluorocarbon and a rare gas to a processing container in which a placing pedestal for placing a processing target object including a first region made of silicon oxide is arranged; b) plasma-processing the processing target object by a first plasma of the process gas generated under a first plasma generation condition; c) plasma-processing the processing target object in which a bias potential is generated on the processing target object by a second plasma of the process gas generated under a second plasma generation condition different from the first plasma generation condition; and d) repeating the b) and the c).

### BRIEF DESCRIPTION OF DRAWINGS

FIG. 1 is a diagram illustrating an example of a plasma processing system according to an embodiment of the present disclosure;

FIG. 2 is a diagram illustrating an example of separation of deposition and etching steps by gas switching;

FIG. 3 is a diagram illustrating an example of separation of the deposition and etching steps by a pulse of an RF signal;

FIG. 4 is a diagram illustrating an example of a structure of a substrate etched by a plasma processing apparatus according to this embodiment;

FIG. 5 is a diagram schematically illustrating an example of a state of an etched substrate;

FIG. 6 is a flowchart illustrating an example of an etching process according to this embodiment;

FIG. 7 is a diagram illustrating an example of RF signals and a state in a processing space according to this embodiment;

FIG. 8 is a diagram illustrating an example of a relation between the RF signals and a deposit or etch amount in this embodiment;

FIG. 9 is a diagram illustrating an example of one cycle of the RF signals in this embodiment;

FIG. 10 is a diagram illustrating an example of experimental results between this embodiment and a comparative example;

FIG. 11 is a diagram illustrating an example of an analysis result based on light emission data for each frequency of RF signals;

FIG. 12 is a diagram illustrating an example of an analysis result based on light emission data for each frequency of RF signals;

FIG. 13 is a diagram illustrating an example of experimental results in a case where a flow volume of fluorocarbon is changed with respect to a flow volume of Ar;

FIG. 14 is a diagram illustrating an example of experimental results in a case where an amount of bias delay is changed;

FIG. 15 is a diagram illustrating an example of experimental results in a case where a pulse frequency and an offset time of the RF signal are changed; and

FIG. 16 is a diagram illustrating an example of a table used for specifying plasma generation conditions.

### DESCRIPTION OF EMBODIMENTS

Exemplary embodiments of a substrate processing method and a substrate processing apparatus disclosed in the present application will be explained below in detail with reference to the accompanying drawings. Incidentally, the disclosed technology is not limited to the embodiments explained below.

In ALE, a process gas used in a deposition step and an ion irradiation step is switched, it takes time to replace the process gas in a processing container. Therefore, a process processing time becomes long, and a throughput decreases. In this regard, it is expected that etching is performed at a higher speed and with a higher selection ratio than a gas switching method.

Configuration of Plasma Processing System 1

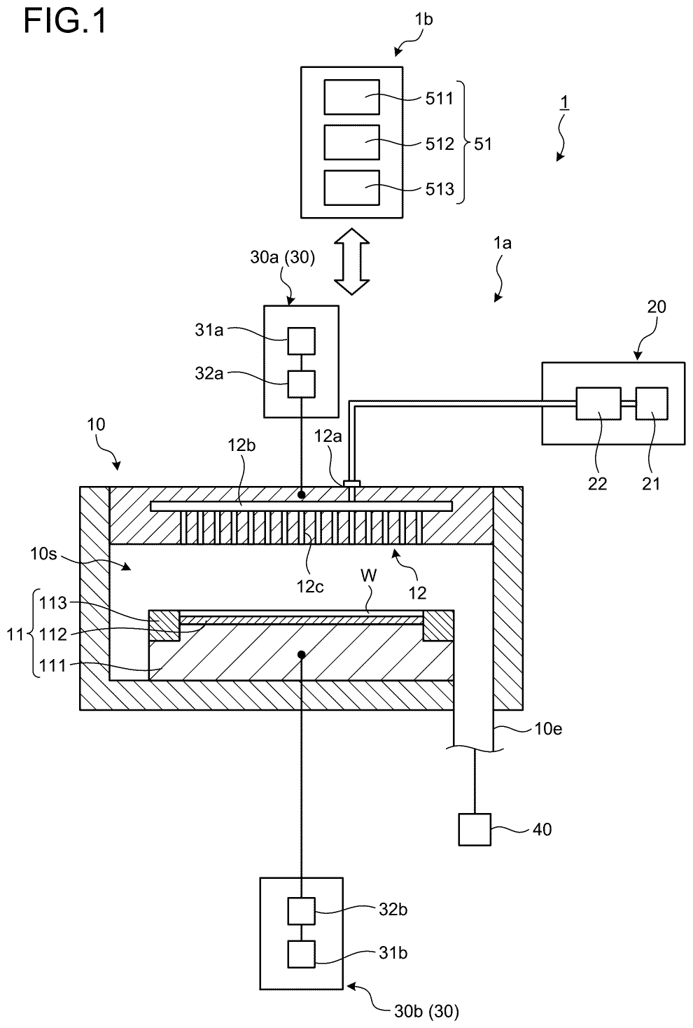

FIG. 1 is a diagram illustrating an example of a plasma processing system according to an embodiment of the present disclosure. As illustrated in FIG. 1, in one embodiment, a plasma processing system 1 includes a plasma processing apparatus 1a and a controller 1b. The plasma processing apparatus 1a is an example of the substrate processing apparatus. The plasma processing apparatus 1a includes a plasma processing chamber 10, a gas supply unit 20, an RF (Radio Frequency) power supply unit 30, and an exhaust system 40. Further, the plasma processing apparatus 1a includes a support unit 11 and an upper electrode shower head 12. The support unit 11 is arranged in a lower region of a plasma processing space 10s in the plasma processing chamber 10. The upper electrode shower head 12 may be arranged above the support unit 11 and function as part of a ceiling of the plasma processing chamber 10.

The support unit 11 is configured to support a substrate W in the plasma processing space 10s. In one embodiment, the support unit 11 includes a lower electrode 111, an electrostatic chuck 112, and an edge ring 113. The electrostatic chuck 112 is arranged on the lower electrode 111 and is configured to support the substrate W on the upper surface of the electrostatic chuck 112. The edge ring 113 is arranged to surround the substrate W on the upper surface of the peripheral edge portion of the lower electrode 111. Further, although not illustrated, in one embodiment, the support unit 11 may include a temperature control module which is configured to adjust at least one of the electrostatic chuck 112 and the substrate W to a target temperature. The temperature control module may include a heater, a flow path, or a combination thereof. A temperature control fluid such as a refrigerant or a heat transfer gas flows through the flow path.

The upper electrode shower head 12 is configured to supply one or more process gases from the gas supply unit 20 to the plasma processing space 10s. In one embodiment, the upper electrode shower head 12 has a gas inlet 12a, a gas diffusion chamber 12b, and a plurality of gas outlets 12c. The gas inlet 12a is in fluid communication with the gas supply unit 20 and the gas diffusion chamber 12b. The plurality of gas outlets 12c fluid-communicate with the gas diffusion chamber 12b and the plasma processing space 10s. In one embodiment, the upper electrode shower head 12 is configured to supply one or more process gases from the gas inlet 12a to the plasma processing space 10s through the gas diffusion chamber 12b and the plurality of gas outlets 12c.

The gas supply unit 20 may include one or more gas sources 21 and one or more flow controllers 22. In one embodiment, the gas supply unit 20 is configured to supply one or more process gases from the corresponding gas sources 21 through the corresponding flow controllers 22 to the gas inlet 12a. Each flow controller 22 may include, for example, a mass flow controller or a pressure control type flow controller. Further, the gas supply unit 20 may include one or more flow modulation devices which modulate or pulse the flow volume of one or more process gases.

The RF power supply unit 30 is configured to supply RF power, for example, one or more RF signals to one or more electrodes such as the lower electrode 111, the upper electrode shower head 12, or both the lower electrode 111 and the upper electrode shower head 12. Accordingly, a plasma is generated from one or more process gases supplied to the plasma processing space 10s. Therefore, the RF power supply unit 30 can function as at least a part of the plasma generation unit configured to generate a plasma from one or more process gases in the plasma processing chamber 10. In one embodiment, the RF power supply unit 30 includes a first RF power supply unit 30a and a second RF power supply unit 30b.

The first RF power supply unit 30a includes a first RF generation unit 31a and a first matching circuit 32a. In one embodiment, the first RF power supply unit 30a is configured to supply the first RF signal from the first RF generation unit 31a through the first matching circuit 32a to the upper electrode shower head 12. For example, the first RF signal may have a frequency in a range of 27 MHz to 100 MHz.

The second RF power supply unit 30b includes a second RF generation unit 31b and a second matching circuit 32b. In one embodiment, the second RF power supply unit 30b is configured to supply a second RF signal from the second RF generation unit 31b through the second matching circuit 32b to the lower electrode 111. For example, the second RF signal may have a frequency in a range of 400 kHz to 13.56 MHz. Instead, a DC (Direct Current) pulse generation unit may be used instead of the second RF generation unit 31b.

Further, although not illustrated, other embodiments can be considered in the present disclosure. For example, in an alternative embodiment, the RF power supply unit 30 may be configured to supply a first RF signal from the RF generation unit to the lower electrode 111, a second RF signal from another RF generation unit to the lower electrode 111, and a third RF signal from still another RF generation unit to the upper electrode shower head 12. In addition, in another alternative embodiment, a DC voltage may be applied to the upper electrode shower head 12.

In various embodiments, the amplitude of one or more RF signals (that is, the first RF signal, the second RF signal, and the like) may be pulsed or modulated. The amplitude modulation may include pulsing the RF signal amplitude between an on state and an off state or between two or more different on states.

For example, the exhaust system 40 may be connected to an exhaust port 10e provided at the bottom of the plasma processing chamber 10. The exhaust system 40 may include a pressure valve and a vacuum pump. The vacuum pump may include a turbo molecular pump, a roughing pump, or a combination thereof.

In one embodiment, the controller 1b processes a computer-executable instruction which causes the plasma processing apparatus 1a to perform various steps described in the present disclosure. The controller 1b may be configured to cause each element of the plasma processing apparatus 1a to execute the various steps described herein. In one embodiment, part or all of the controller 1b may be included in the plasma processing apparatus 1a. For example, the controller 1b may include a computer 51. The computer 51 may include, for example, a processor (CPU: Central Processing Unit) 511, a storage unit 512, and a communication interface 513. The processor 511 may be configured to perform various control operations on the basis of the program stored in the storage unit 512. The storage unit 512 may include a RAM (Random Access Memory), a ROM (Read Only Memory), an HDD (Hard Disk Drive), an SSD (Solid State Drive), or a combination thereof. The communication interface 513 may communicate with the plasma processing apparatus 1a through a communication line such as a LAN (Local Area Network).

Comparison of ALE Methods

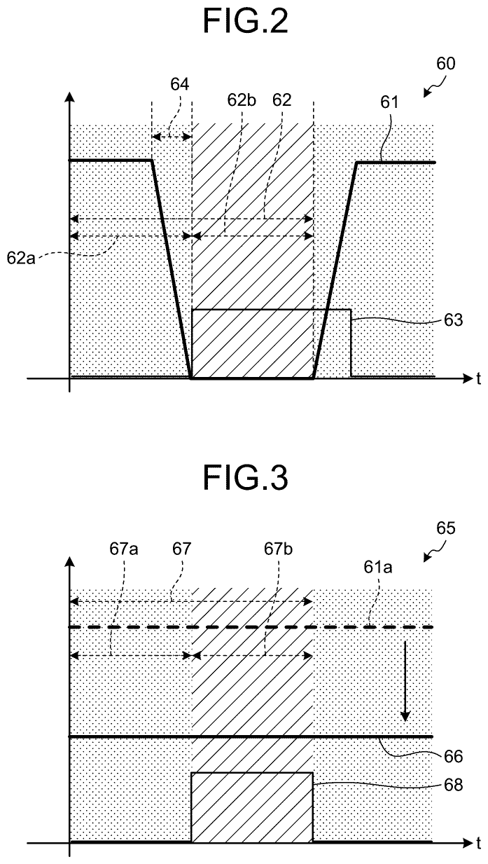

Herein, with reference to FIGS. 2 and 3, the control image of QuasiALE (hereinafter, also referred to as Q-ALE) by the gas switching method and PulseALE by an RF switching method according to this embodiment is compared. Incidentally, in the following description, the deposition step and the ion irradiation step are referred to as a deposition step and an etching step, respectively. FIG. 2 is a diagram illustrating an example of separation of the deposition and etching steps by gas switching. FIG. 3 is a diagram illustrating an example of separation of the deposition and etching steps by a pulse of the RF signal.

In a graph 60 illustrated in FIG. 2, the ratio of fluorocarbon to the rare gas of the process gas is illustrated in a graph 61. The Q-ALE has a deposition step 62a in which fluorocarbon is supplied and an etching step 62b in which no fluorocarbon is supplied, and a rare gas such as an Ar gas is supplied. That is, a section 62 for one cycle of the Q-ALE is configured by the deposition step 62a and the etching step 62b. Further, in the etching step 62b, a bias voltage 63 is applied. At this time, when the section 62 is, for example, four to seven seconds, a section 64 for switching the process gas from the deposition step 62a to the etching step 62b takes about 0.5 to one second.

A graph 65 illustrated in FIG. 3 becomes a graph 66 in which the ratio of fluorocarbon to the rare gas of the process gas is lower than that of the graph 61a corresponding to the ratio in the deposition step 62a of the Q-ALE. The PulseALE has a deposition step 67a in which only the first RF signal is supplied to the upper electrode shower head 12 and an etching step 67b in which only the second RF signal is supplied to the lower electrode 111. That is, a section 67 for one cycle of PulseALE is configured by the deposition step 67a and the etching step 67b. In the graph 65, the second RF signal is shown in a graph 68. At this time, the section 67 is, for example, one millisecond (1000 microseconds), and the switching of the RF signal from the deposition step 67a to the etching step 67b is sufficiently faster than the switching of the process gas. In this embodiment, the deposition step 67a for radical adsorption and the etching step 67b for ion-assisted withdrawal reaction are independently controlled. Incidentally, in the following description, milliseconds and microseconds are expressed as “ms” and “μs”, respectively.

Configuration of Substrate W

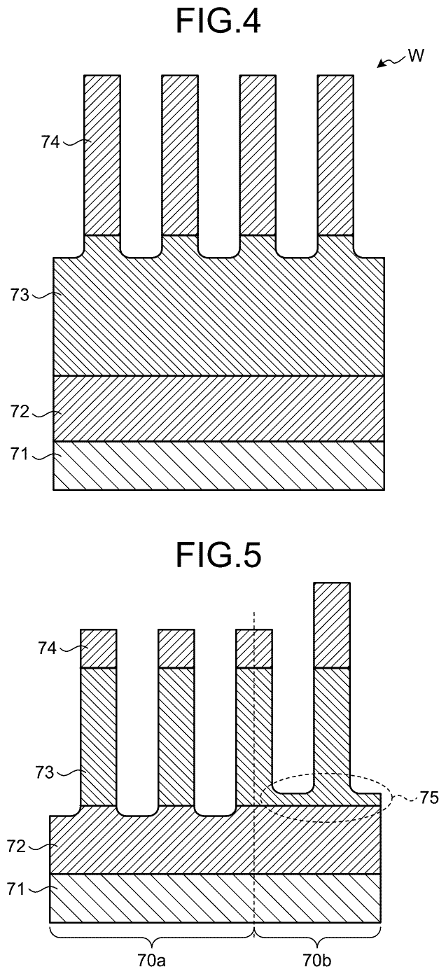

FIG. 4 is a diagram illustrating an example of a structure of a substrate etched by the plasma processing apparatus according to this embodiment.

As illustrated in FIG. 4, for example, the substrate W has a silicon nitride film 72, a silicon oxide film 73, and a mask 74 on a silicon substrate 71. The silicon nitride film 72 is an etching stop layer. The silicon oxide film 73 is an etching target film. The mask 74 is a silicon nitride film and has a predetermined pattern of openings, for example, comb-shaped openings. In the etching according to this embodiment, the silicon oxide film 73 at the opening portion of the mask 74 is etched until the etching reaches the silicon nitride film 72. At this time, since the opening of the mask 74 is narrow, and the aspect ratio of the groove formed by etching is high, there is a trade-off relation between the removability and the mask selection ratio.

FIG. 5 is a diagram schematically illustrating an example of a state of the etched substrate. A region 70a in FIG. 5 is an example of a normal state in which the silicon oxide film 73 is etched until the etching reaches the silicon nitride film 72. On the other hand, a region 70b is an example of a state in which the silicon oxide film 73 is not etched until the etching reaches the silicon nitride film 72, the etching is stopped in the middle, and a poor removal occurs as illustrated in a region 75. In this embodiment, various conditions are set such that the result of the plasma processing becomes the normal state illustrated in the region 70a.

Etching Method

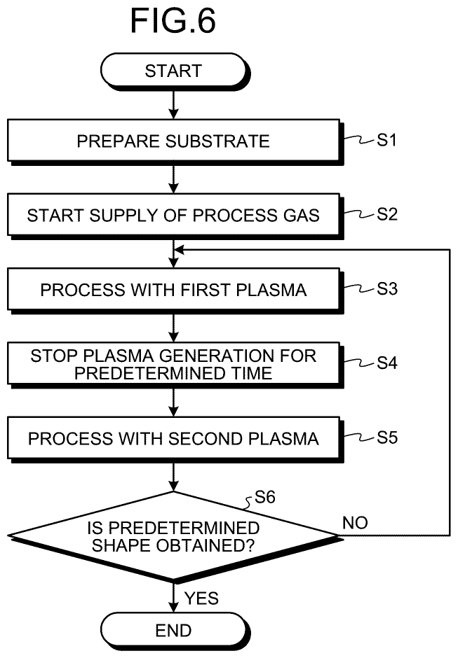

Next, the etching method according to this embodiment will be described. FIG. 6 is a flowchart illustrating an example of an etching process according to this embodiment.

In the etching method according to this embodiment, the controller 1b opens an opening portion (not illustrated), and the substrate W on which the mask 74 is formed on the silicon oxide film 73 is carried into the plasma processing chamber 10 and is mounted on the electrostatic chuck 112 of the support unit 11 (placing pedestal). The substrate W is held by the electrostatic chuck 112 by applying a DC voltage to the electrostatic chuck 112. Thereafter, the controller 1b closes the opening portion and causes the exhaust system 40 to exhaust a gas from the plasma processing space 10s so that the atmosphere of the plasma processing space 10s becomes a predetermined degree of vacuum. Further, the controller 1b causes a temperature control module (not illustrated) to adjust temperature so that the temperature of the substrate W becomes a predetermined temperature (Step S1).

Next, the controller 1b starts supplying the process gas (Step S2). The controller 1b supplies a mixed gas of C4F6, O2, and Ar (hereinafter, referred to as C4F6/O2/Ar gas) as a process gas containing fluorocarbon and a rare gas to the gas inlet 12a. Incidentally, the fluorocarbon may be other compounds having a carbon-fluorine bond such as CF2 and C3F4. The process gas is supplied to the gas inlet 12a and then supplied to the gas diffusion chamber 12b for diffusion. After being diffused in the gas diffusion chamber 12b, the process gas is supplied in a shower shape through the plurality of gas outlets 12c to the plasma processing space 10s of the plasma processing chamber 10 and is added in the plasma processing space 10s.

The controller 1b causes the RF power supply unit 30 to supply the first RF signal (first RF power) for plasma excitation to the upper electrode shower head 12. Plasma is generated in the plasma processing space 10s when the first RF signal for plasma excitation is supplied to the upper electrode shower head 12. That is, in the plasma processing space 10s, radicals and ions are generated by the first RF signal. The substrate W is plasma-processed by the generated plasma. That is, the controller 1b plasma-processes the substrate W with the first plasma of the process gas generated under a first plasma generation condition (Step S3). The first plasma mainly generates fluorocarbon radicals and ions. The substrate W is exposed to the first plasma, and deposits containing fluorocarbon adhere on the silicon oxide film 73 and the mask 74. That is, Step S3 corresponds to the deposition step 67a illustrated in FIG. 3.

The controller 1b causes the RF power supply unit 30 to stop the supply of the first RF signal and stops the plasma generation for a predetermined time (Step S4). At this time, the supply of the second RF signal is also stopped.

The controller 1b causes the RF power supply unit 30 to supply a second RF signal (second RF power) for plasma excitation and bias to the lower electrode 111. Plasma is generated in the plasma processing space 10s when the second RF signal for plasma excitation and bias is supplied to the lower electrode 111. That is, in the plasma processing space 10s, radicals and ions are generated, and ion energy is controlled by the second RF signal. The substrate W is plasma-processed by the generated plasma. That is, the controller 1b plasma-processes the substrate W with the second plasma of the process gas generated under a second plasma generation condition (Step S5). The second plasma mainly generates Ar ions. The substrate W is exposed to the second plasma, and the silicon oxide film 73 is etched. That is, when Ar ions are drawn toward the lower electrode 111 side by bias potentials, the substrate W is etched by the interaction between the deposits on the silicon oxide film 73 and the Ar ions. Incidentally, in the following description, the deposit on the silicon oxide film 73 and the deposit on the mask 74 may be omitted.

That is, by the radicals of one or more active species of atoms and molecules derived from fluorocarbon, for example, one or more active species of fluorine and fluorocarbon, deposit deposits on the silicon oxide film 73, and the silicon oxide film 73 is etched by the interaction between the deposits on the silicon oxide film 73 and the Ar ions drawn by the bias potentials. Incidentally, similarly, the mask 74 is etched by the interaction between the deposits on the mask 74 and the Ar ions drawn by the bias potentials, but an etching rate is significantly lower than that of the silicon oxide film 73.

The controller 1b judges whether or not a predetermined shape is obtained in Steps S3 to S5 (Step S6). In a case where it is judged that the predetermined shape is not obtained (Step S6: No), the controller 1b returns the process to Step S3. On the other hand, in a case where it is judged that the predetermined shape is obtained (Step S6: Yes), the controller 1b ends the process. Incidentally, the controller 1b may include a step between Steps S5 and S6 in which the supply of the first RF signal and the second RF signal is stopped, and a conveyed product is exhausted.

In a case where the process is ended, the controller 1b stops the supply of the process gas. Further, the controller 1b applies a DC voltage having opposite positive and negative directions to the electrostatic chuck 112 to eliminate static electricity, and the substrate W is peeled off from the electrostatic chuck 112. The controller 1b opens the opening portion (not illustrated). The substrate W is carried out from the plasma processing space 10s of the plasma processing chamber 10 through the opening portion. As described above, in the plasma processing system 1, the etching can be performed at a higher speed and a higher selection ratio than the gas switching method.

Details of PulseALE

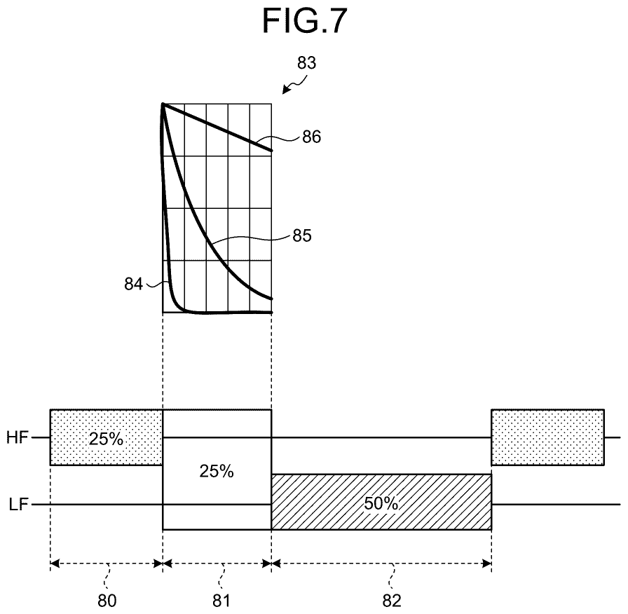

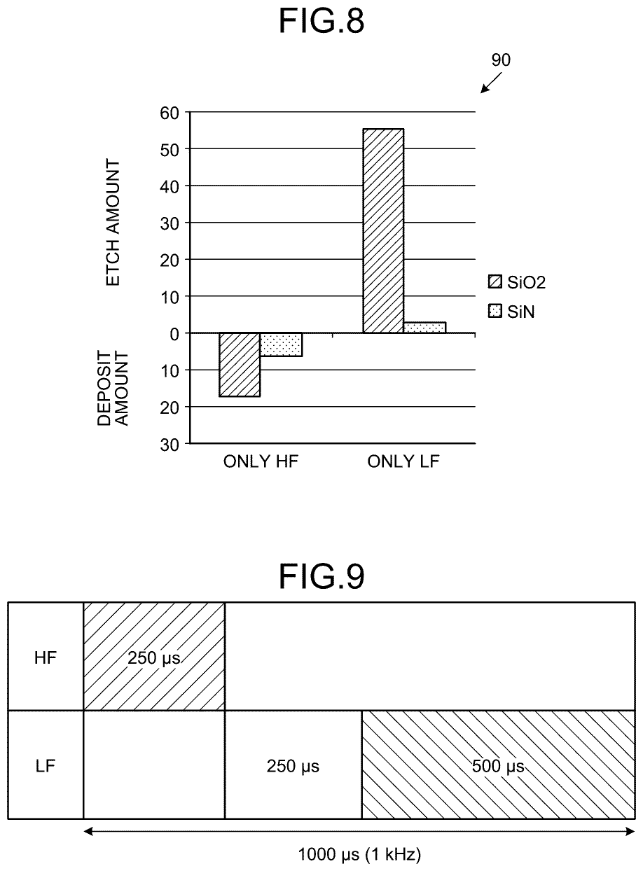

Next, the details of Steps S3 to S5 will be described with reference to FIGS. 7 and 8. FIG. 7 is a diagram illustrating an example of the RF signals and a state in a processing space according to this embodiment. As illustrated in FIG. 7, in this embodiment, the deposition and the etching are repeated by repeating sections 80 to 82 corresponding to Steps S3 to S5. One cycle of the sections 80 to 82 is repeated, for example, at 1 kHz (1000 μs). Incidentally, in the following description and drawings, the first RF signal may be expressed as HF (High Frequency) and the second RF signal may be expressed as LF (Low Frequency).

First, in the section 80 corresponding to Step S3, the first RF signal (HF) is supplied, and the substrate W is plasma-processed by the first plasma. In the section 80, no second RF signal (LF) is supplied. The section 80 is, for example, 25% of the time of one cycle.

Next, in the section 81, neither the first RF signal (HF) nor the second RF signal (LF) is supplied. A graph 83 illustrates the state of the plasma processing space 10s in the section 81. As illustrated in the graph 83, a plasma potential 84 drops rapidly when the supply of the first RF signal (HF) is stopped and becomes almost zero. On the other hand, the ion 85 decreases when the supply of the first RF signal (HF) is stopped, but remains slightly even when the supply of the second RF signal (LF) is started. Further, the radical 86 gradually decreases even when the supply of the first RF signal (HF) is stopped, and a considerable amount remains even when the supply of the second RF signal (LF) is started. That is, in the section 81, a change in the radical/ion ratio and a decrease in the electron temperature occur. The section 81 is, for example, 25% of the time of one cycle. Incidentally, in the graph 65 of FIG. 3, the section corresponding to the section 81 is not provided.

Subsequently, in section 82, the second RF signal (LF) is supplied, and the substrate W is plasma-processed by the second plasma. In the section 82, the first RF signal (HF) is not supplied. In the section 82, the ions and radicals remaining in the plasma processing space 10s in the section 81 are drawn to the lower electrode 111 side by the bias potential, so that the silicon oxide film 73 is mainly etched. In the section 82, by providing the section 81, the variation in the ion incident angle can be suppressed, and a narrow slit is etched effectively. The section 82 is, for example, 50% of the time of one cycle. Thereafter, when Steps S3 to S5 are repeated by the controller 1b, the sections 80 to 82, that is, the deposition and the etching are repeated, and the etching of the silicon oxide film 73 proceeds.

FIG. 8 is a diagram illustrating an example of a relation between the RF signals and a deposit amount or an etch amount in this embodiment. As illustrated in a graph 90 of FIG. 8, in a case where only the first RF signal (HF) is supplied, both the silicon oxide film (SiO2) and the silicon nitride film (SiN) are in a deposition mode in which a deposit adheres. Incidentally, the deposit amount in the silicon oxide film (SiO2) is about 2.5 times larger than that in the silicon nitride film (SiN). On the other hand, in a case where only the second RF signal (LF) is supplied, both the silicon oxide film (SiO2) and the silicon nitride film (SiN) are in an etching mode in which etching proceeds. Herein, since the silicon oxide film (SiO2) has about 25 times more etch amount than the silicon nitride film (SiN), the mask loss of the mask which is the silicon nitride film (SiN) can be reduced and the mask selection ratio can be improved.

Experimental Results

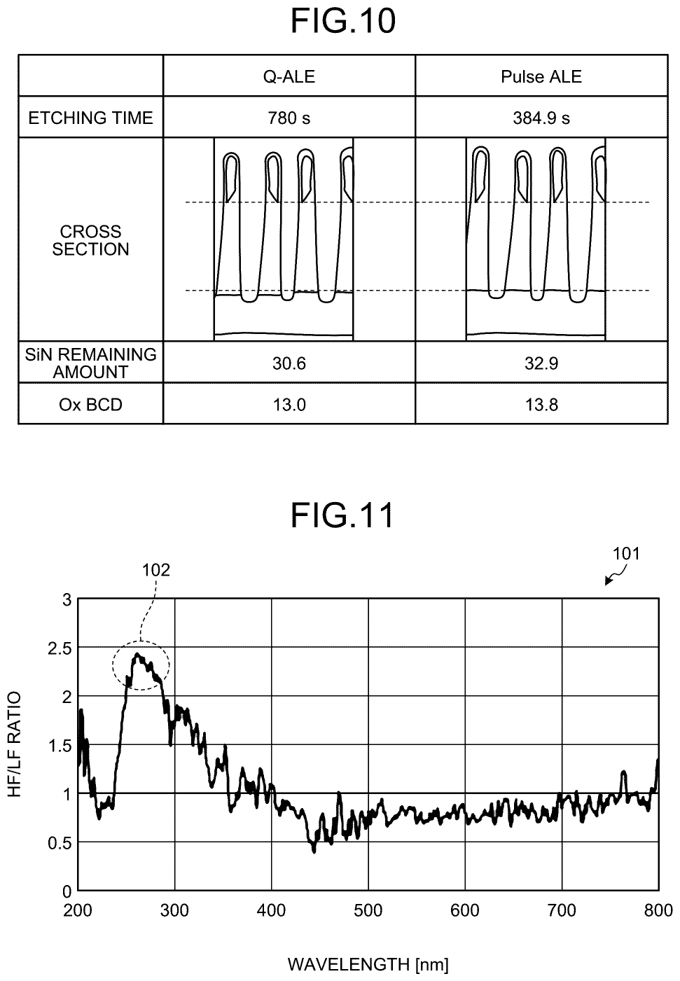

Next, experimental results will be described with reference to FIGS. 9 and 10. FIG. 9 is a diagram illustrating an example of one cycle of the RF signals in this embodiment. As illustrated in FIG. 9, in this experiment, one cycle is 1000 μs (1 kHz). Further, the supply time of the first RF signal (HF) corresponding to the section 80 in FIG. 7 is set to 250 μs, the stop time of the first RF signal (HF) and the second RF signal (LF) corresponding to the section 81 is set to 250 μs, and the supply time of the second RF signal (LF) corresponding to the section 82 is set to 500 μs.

Processing Conditions

Pressure in plasma processing chamber 10: 30 m Torr (4.00 Pa)

Temperature: 100° C.

First RF signal power (60 MHz): 400 W (pulse)

Second RF signal power (13 MHz): 200 W (pulse)

Pulse frequency: 1 kHz

Pulse duty: HF/LF/LF offset

=25/50/50%

Process gas

Flow ratio of (C4F6/O2/Ar): 0.29/0.34/100

FIG. 10 is a diagram illustrating an example of experimental results between this embodiment and a comparative example. FIG. 10 illustrates the experimental results of PulseALE according to this embodiment and Q-ALE which is a comparative example. Incidentally, in the Q-ALE, regarding the process gas, C4F6/O2/Ar gas was used in the deposition step, Ar gas was used in the etching step, the deposition step was set to 2.5 s, and the etching step was set to 3.5 s. Further, a Line and Space pattern with a pitch of 25 nm was used as an etching sample, Line CD (Critical Dimension) was set to 12 nm, Space CD was set to 13 nm, and a silicon oxide film thickness was set to 50 nm.

First, an etching time could be shortened to 384.9 s in the PulseALE compared to 780 s in the Q-ALE. Further, in the cross section, it can be seen that both the Q-ALE and the PulseALE pass through the silicon oxide film and reach the silicon nitride film of the etching stop layer. It can be seen that the remaining amount of the silicon nitride film (SiN remaining amount) which is a mask is 32.9 nm in PulseALE compared with 30.6 nm in Q-ALE, and the mask selection ratio is improved. It can be seen that the CD value (bottom CD: OxBCD) of the silicon oxide film immediately above the etching stop layer is 13.0 nm in Q-ALE and 13.8 nm in PulseALE which are almost the same. As described above, in the PulseALE according to this embodiment, the throughput can be improved while realizing the mask selection ratio (SiN selection ratio) equal to or higher than that of the Q-ALE.

Analysis Result

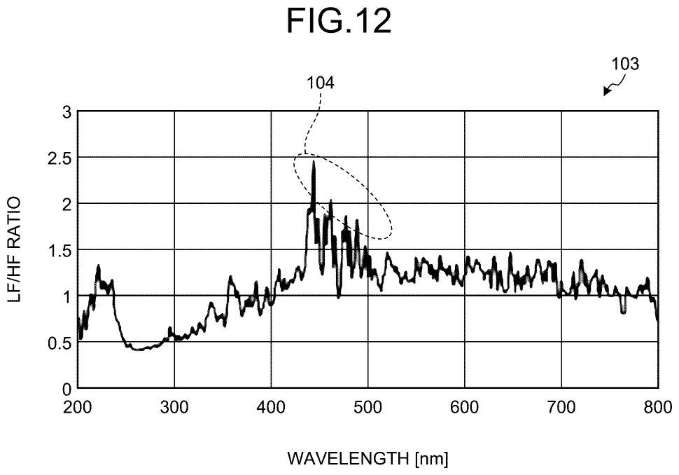

Next, an analysis result by an OES (Optical Emission Sensor) in PulseALE will be described with reference to FIGS. 11 and 12. FIGS. 11 and 12 are diagrams illustrating examples of the analysis results based on light emission data of each frequency of the RF signals. A graph 101 illustrated in FIG. 11 is a graph for a ratio (hereinafter referred to as an HF/LF ratio) between the light emission data of the first RF signal (HF, 60 MHz) and the light emission data of the second RF signal (LF, 13 MHz) for each wavelength. In the graph 101, as illustrated in a region 102, a peak in the wavelength region corresponding to a carbon (C)-containing molecule (CF system) appears strongly.

On the other hand, a graph 103 illustrated in FIG. 12 is a graph for a ratio (hereinafter referred to as an LF/HF ratio) between the light emission data of the second RF signal (LF, 13 MHz) and the light emission data of the first RF signal (HF, 60 MHz) for each wavelength. In the graph 103, as illustrated in a region 104, a peak in the wavelength region corresponding to argon (Ar) appears strongly. From this, in the PulseALE, in a case where the RF signal of 60 MHz is used for the first RF signal, and the RF signal of 13 MHz is used for the second RF signal, the deposition step and the etching step can be separated as in the Q-ALE.

Effect of Ar Dilution

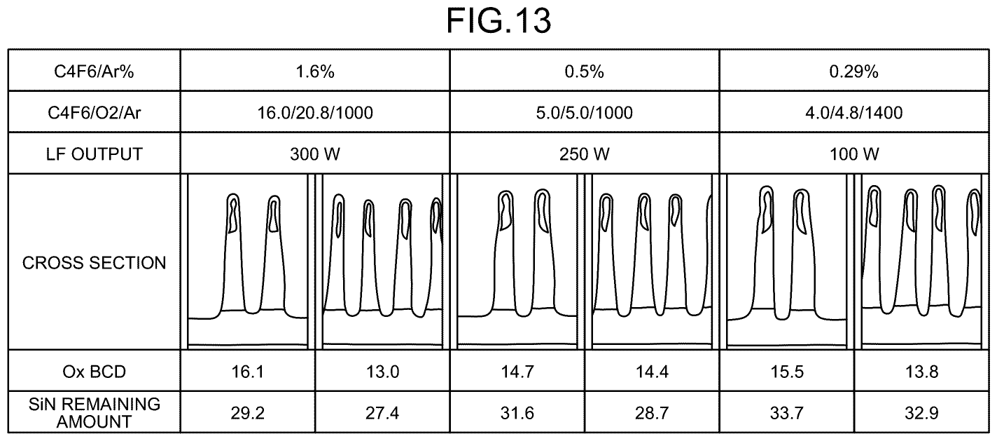

Next, the effect of diluting a C4F6 gas with an Ar gas will be described with reference to FIG. 13. FIG. 13 is a diagram illustrating an example of experimental results in a case where a flow volume of fluorocarbon is changed with respect to a flow volume of Ar. In the example of FIG. 13, cases where the flow ratios of the C4F6 gas to the Ar gas are set to 1.6%, 0.5%, and 0.29%, and the O2 gas and the LF output are optimized are compared. Further, as the pattern on the substrate W, two patterns of 2Line in which only two lines are lined up and Dense in which a plurality of lines (four of the Lines in the drawing) are lined up were used among Line and Space patterns. The Dense is the same as the sample illustrated in FIG. 10. Incidentally, the other processing conditions are as follows. Further, as the optimization of the LF output, the increase of the flow volume of Ar causes the polymer deposited on the mask to become thinner. Thus, the LF output was adjusted so that the mask was not be scraped.

Processing Conditions

Pressure in plasma processing chamber 10: 30 m Torr (4.00 Pa)

Temperature: 100° C.

First RF signal power (60 MHz): 400 W (pulse)

Second RF signal power (13 MHz): 200 W (pulse)

Pulse frequency: 1 kHz

Pulse duty: HF/LF/LF offset

=25/50/50%

In the case of the flow ratio of 1.6%, the flow volume ratio of C4F6/O2/Ar gas was 1.6/2.1/100, and the LF output was 300 W. As a result, the CD value (OxBCD) of the silicon oxide film directly above the etching stop layer was 16.1 nm for the 2Line and 13.0 nm for the Dense. Further, the remaining amount of the silicon nitride film (SiN remaining amount) was 29.2 nm for the 2Line and 27.4 nm for the Dense.

In the case of the flow ratio of 0.5%, the flow volume ratio of C4F6/O2/Ar gas was 0.5/0.5/100, and the LF output was 250 W. As a result, the CD value (OxBCD) of the silicon oxide film was 14.7 nm for the 2Line and 14.4 nm for the Dense. Further, the remaining amount of the silicon nitride film (SiN remaining amount) was 31.6 nm for the 2Line and 28.7 nm for the Dense.

In the case of the flow ratio of 0.29%, the flow volume ratio of C4F6/O2/Ar gas was 0.29/0.34/100, and the LF output was 100 W. As a result, the CD value (OxBCD) of the silicon oxide film was 15.5 nm for the 2Line and 13.8 nm for the Dense. Further, the remaining amount of the silicon nitride film (SiN remaining amount) was 33.7 nm for the 2Line and 32.9 nm for the Dense. From the above, it can be seen that the remaining amount (SiN remaining amount) of the silicon nitride film is the largest in the case of the flow ratio of 0.29%, and the mask selection ratio is improved by significantly diluting a C4F6 gas with an Ar gas. In other words, by suppressing the increase in the amount of CxFy radicals due to the dissociation at the time of supplying LF, an effect of separating the deposition and the etching is increased, and a controllability of each of the deposition and the etching is improved, so that the mask selection ratio can be further improved. Incidentally, the amount of radicals reduced by Ar dilution can be adjusted by the output at the time of supplying HF.

Effect of Bias Offset

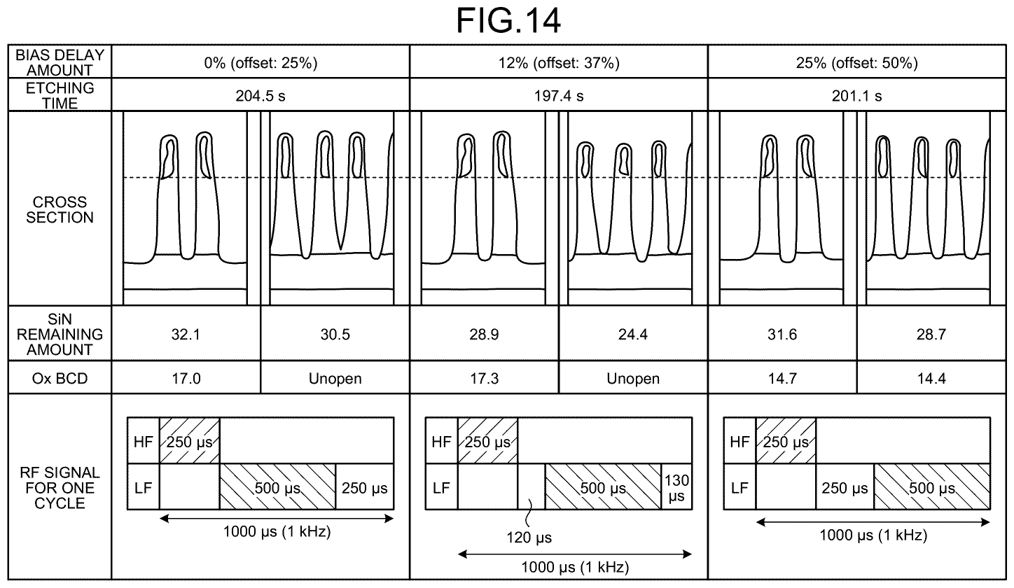

Next, the effect of the case of offsetting the timing of supplying LF will be described with reference to FIG. 14. FIG. 14 is a diagram illustrating an example of experimental results in a case where an amount of bias delay is changed. In the example of FIG. 14, cases where the timing of supplying LF, that is, the timing of applying the bias potential is delayed by 0%, 12%, and 25% with reference to 250 μs at which the supply of HF ends in 1000 μs are compared. Incidentally, when the bias delay is expressed by an offset, the delay amount of 0% is the offset amount of 25%, the delay amount of 12% is the offset of 37%, and the delay amount of 25% is the offset of 50%. Further, as the pattern on the substrate W, two patterns of 2Line in which only two lines are lined up and Dense in which a plurality of lines are lined up were used among Line and Space patterns. Incidentally, the other processing conditions are as follows.

Processing Conditions

Pressure in plasma processing chamber 10: 30 m Torr (4.00 Pa)

Temperature: 100° C.

First RF signal power (60 MHz): 200 W (pulse)

Second RF signal power (13 MHz): 500 W (pulse)

Pulse frequency: 1 kHz

Pulse duty: HF/LF=25/50%

Process gas

Flow ratio of (C4F6/O2/Ar): 0.5/0.5/100

In the case of the delay amount of 0%, the etching time was 204.5 s, and the remaining amount of the silicon nitride film (SiN remaining amount) was 32.1 nm for the 2Line and 30.5 nm for the Dense. Further, the CD value (OxBCD) of the silicon oxide film was 17.0 nm for the 2Line and did not reach (Unopen) the etching stop layer for the Dense.

In the case of the delay amount of 12%, the etching time was 197.4 s, and the remaining amount of the silicon nitride film (SiN remaining amount) was 28.9 nm for the 2Line and 24.4 nm for the Dense. Further, the CD value (OxBCD) of the silicon oxide film was 17.3 nm for the 2Line and did not reach (Unopen) the etching stop layer for the Dense.

In the case of the delay amount of 25%, the etching time was 201.1 s, and the remaining amount of the silicon nitride film (SiN remaining amount) was 31.6 nm for the 2Line and 28.7 nm for the Dense. Further, the CD value (OxBCD) of the silicon oxide film was 14.7 nm for the 2Line and 14.4 nm for the Dense. From the above, it can be seen that by delaying the timing of supplying LF, the potential at the time of supplying LF is increased, and the removability and the mask selection ratio are improved. It is considered that this is because the plasma is deactivated, the electron temperature is lowered, and the verticality of the ions is increased.

Pulse Frequency and Offset Time

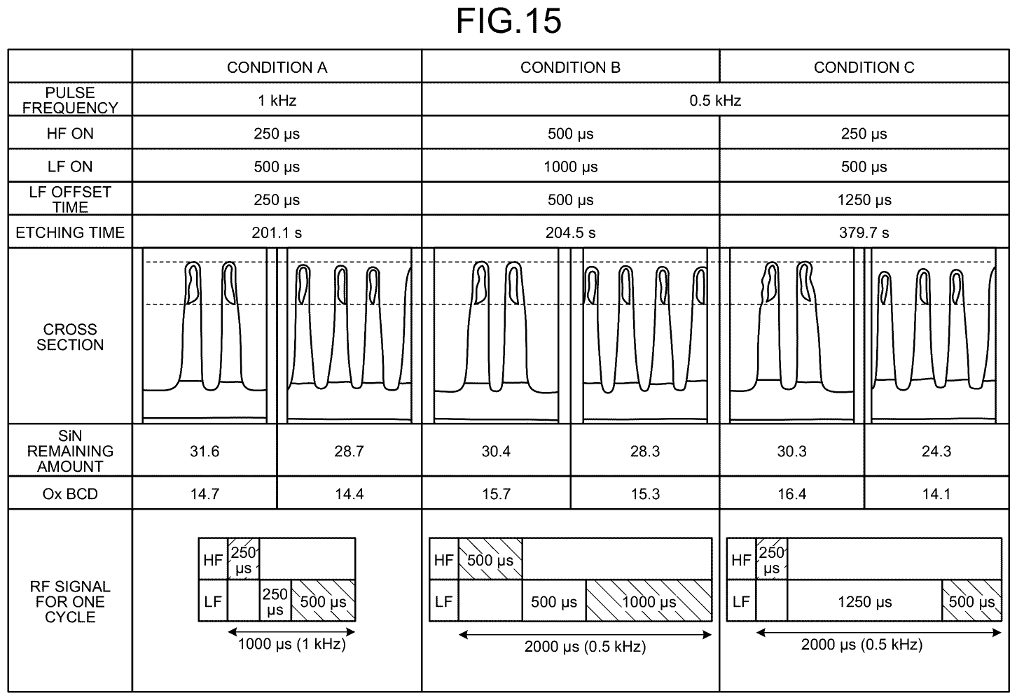

Next, experimental results in a case where the pulse frequency and the offset time are changed will be described with reference to FIG. 15. FIG. 15 is a diagram illustrating an example of the experimental results in a case where the pulse frequency and the offset time of the RF signal are changed. In the example of FIG. 15, a condition A where the pulse frequency is set to 1 kHz, and the offset time of the LF is set to 250 μs, a condition B where the pulse frequency is set to 0.5 kHz, and the offset time of the LF is set to 500 μs, and a condition C where the pulse frequency is set to 0.5 kHz, and the offset time of the LF is set to 1250 μs are compared. Further, as the pattern on the substrate W, two patterns of 2Line in which only two lines are lined up and Dense in which a plurality of lines are lined up were used among Line and Space patterns. Incidentally, the other processing conditions are as follows.

Processing Conditions

Pressure in plasma processing chamber 10: 30 m Torr (4.00 Pa)

Temperature: 100° C.

First RF signal power (60 MHz): 200 W (pulse)

Second RF signal power (13 MHz): 500 W (pulse)

Process gas

Flow ratio of (C4F6/O2/Ar): 0.5/0.5/100

In the case of the condition A, the pulse frequency was set to 1 kHz, the supply time (HF ON) of the HF was set to 250 μs, the supply time (LF ON) of the LF was set to 500 μs, and the offset time of the LF was set to 250 μs. As a result, the etching time was 201.1 s, and the remaining amount (SiN remaining amount) of the silicon nitride film was 31.6 nm for the 2Line and 28.7 nm for the Dense. Further, the CD value (OxBCD) of the silicon oxide film was 14.7 nm for the 2Line and 14.4 nm for the Dense.

In the case of the condition B, the pulse frequency was set to 0.5 kHz, the supply time (HF ON) of the HF was set to 500 μs, the supply time (LF ON) of the LF was set to 1000 μs, and the offset time of the LF was set to 500 μs. As a result, the etching time was 204.5 s, and the remaining amount (SiN remaining amount) of the silicon nitride film was 30.4 nm for the 2Line and 28.3 nm for the Dense. Further, the CD value (OxBCD) of the silicon oxide film was 15.7 nm for the 2Line and 15.3 nm for the Dense.

In the case of the condition C, the pulse frequency was set to 0.5 kHz, the supply time (HF ON) of the HF was set to 250 μs, the supply time (LF ON) of the LF was set to 500 μs, and the offset time of the LF was set to 1250 μs. As a result, the etching time was 379.7 s, and the remaining amount (SiN remaining amount) of the silicon nitride film was 30.3 nm for the 2Line and 24.3 nm for the Dense. Further, the CD value (OxBCD) of the silicon oxide film was 16.4 nm for the 2Line and 14.1 nm for the Dense. From the above, it can be seen that when comparing the condition A and the condition B, the results are the same, and when comparing the condition A and the condition C, the potential rises excessively when the offset time is excessively long, and the mask selection ratio deteriorates. That is, when the offset time of LF becomes long, the removability of the narrow slit is improved, but the remaining amount of the mask tends to decrease. It is presumed that this is because when the time after the supply of HF is stopped becomes long, the plasma density at the time of supplying LF decreases, and the plasma potential and ion energy at the time of supplying LF increase. Therefore, in the case of the condition that the balance between the deposition and the etching changes by making a difference in the mixing ratio of the process gas and the HF/LF output ratio, the mask selection ratio and the removability can be optimized by the offset time of LF.

Specification of Plasma Generation Conditions

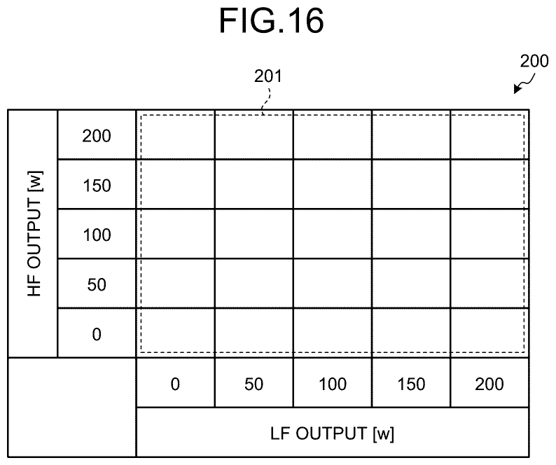

Subsequently, the specification of the plasma generation conditions will be described with reference to FIG. 16. FIG. 16 is a diagram illustrating an example of a table used for specifying plasma generation conditions. A table 200 illustrated in FIG. 16 is an example of a table in which the result of the light emission data of the OES and a bias value is input for the combination of HF output (first RF power) and LF output (second RF power) with the conditions of the process gas fixed.

First, the controller 1b fixes the conditions of the process gas, and individually supplies the HF output (first RF power) and the LF output (second RF power) at a plurality of output values into the plasma processing chamber (processing container) 10. For example, the controller 1b sets the HF output to 0 W and supplies the LF output such that the LF output increases by 50 W from 0 W. Next, the controller 1b sets the HF output to 50 W and supplies the LF output such that the LF output increases by 50 W from 0 W. In this way, when supplying the HF output (first RF power) and the LF output (second RF power) with changing, the controller 1b acquires each of the light emission data and the bias value so as to fill a matrix 201 of the table 200. Incidentally, the values of the HF output and the LF output in the table 200 are examples, and the light emission data and the bias value when the output is made larger may be acquired.

Herein, the light emission data is the data of the active species in the plasma processing space 10s. Further, the active species are active species such as CF system, CF/Ar ratio, and Ar system, for example, active species of data corresponding to the region 102 and the region 104 of FIGS. 11 and 12. Further, the bias value is a value such as Vpp or Vdc, that is, bias potential data.

When the controller 1b generates each table 200 in which the acquired light emission data and bias value data are input, the controller 1b specifies the first plasma generation condition on the basis of each table 200. From each matrix 201, the controller 1b specifies the combination of the HF output (first RF power) and the LF output (second RF power) corresponding to the data in which the numerical value for the CF active species is higher than the other data, and the bias potential of the bias value is zero as the first plasma generation condition. That is, the controller 1b specifies the first plasma generation condition in the deposition step.

Next, from each matrix 201, the controller 1b specifies the combination of the HF output (first RF power) and the LF output (second RF power) corresponding to the data in which the numerical value for the CF active species is lower than the other data, and the bias potential of the bias value is higher than a predetermined value as the second plasma generation condition. That is, the controller 1b specifies the second plasma generation condition in the etching step (activation step). Accordingly, it is possible to specify more effective plasma generation conditions.

Hereinbefore, according to this embodiment, the controller 1b executes a step a) of supplying a process gas containing fluorocarbon and a rare gas to the processing container (plasma processing chamber 10) in which a placing pedestal (support unit 11) for placing a processing target object (substrate W) including the first region made of silicon oxide is arranged. The controller 1b executes a step b) of plasma-processing the processing target object by the first plasma of the process gas generated under the first plasma generation condition. The controller 1b executes a step c) of plasma-processing the processing target object in which a bias potential is generated on the processing target object by the second plasma of the process gas generated under the second plasma generation condition different from the first plasma generation condition. The controller 1b executes a step d) of repeating b) and c). As a result, the etching can be performed at a higher speed and a higher selection ratio than the gas switching method.

According to this embodiment, the condition of the process gas introduced in b) and the condition of the process gas introduced in c) are the same condition. As a result, since the process gas is not switched, the deposition step and the etching step can be switched at a high speed.

According to this embodiment, the numerical value regarding the fluorocarbon generated in b) is higher than the numerical value regarding the fluorocarbon generated in c). As a result, the amount of radicals and ions generated by the first plasma can be increased.

According to this embodiment, the numerical value regarding fluorocarbon is the amount of active species of fluorocarbon. As a result, the amount of radicals and ions generated by the first plasma can be increased.

According to this embodiment, the numerical value regarding fluorocarbon is the amount of active species of fluorocarbon with respect to the active species of rare gas. As a result, the effect of separating the deposition and the etching is increased, and the controllability of each of the deposition and the etching is improved, so that the mask selection ratio can be improved.

According to this embodiment, the controller 1b executes the step e) of not generating plasma. d) repeats b), e), and c) in the order of b), e), and c). As a result, a desired shape can be obtained on the processing target object (substrate W) by etching.

According to this embodiment, the condition of the process gas introduced in e) is the same as the condition of the process gas introduced in b) and c). As a result, since the process gas is not switched, the deposition step and the etching step can be switched at a high speed.

According to this embodiment, the time of e) is 250 microseconds or more and less than 1250 microseconds. As a result, a desired shape can be obtained on the processing target object (substrate W) by etching.

According to this embodiment, the first plasma is generated by supplying the first RF power having the first frequency into the processing container, and the first frequency is 40 MHz or more. As a result, deposits can be formed on the processing target object (substrate W).

According to this embodiment, the second plasma is generated by supplying the second RF power having the second frequency into the processing container, and the second frequency is 13.56 MHz or less. As a result, the processing target object (substrate W) can be etched.

According to this embodiment, the second RF power is supplied to the placing pedestal. As a result, the processing target object can be etched when radicals and ions are drawn to the processing target object (substrate W) side.

According to this embodiment, the first plasma generation condition and the second plasma generation condition are the same conditions except the condition regarding RF power. As a result, the deposition step and the etching step can be switched at a high speed.

According to this embodiment, in the process gas, the flow volume of fluorocarbon is 0.5% or less with respect to the flow volume of rare gas. As a result, the mask selection ratio can be further improved.

According to this embodiment, the processing target object has a second region made of silicon nitride, and the first region is selectively etched with respect to the second region. As a result, a desired shape can be obtained on the processing target object (substrate W).

According to this embodiment, b) forms a deposit containing fluorocarbon on the processing target object, and c) etches the first region by the interaction between the deposit and the ions of the rare gas which are generated by the second plasma and incident on the processing target object on the placing pedestal by the bias potential. As a result, a desired shape can be obtained on the processing target object (substrate W).

According to this embodiment, the data of the active species and bias potential when the condition of the process gas is fixed, and the first RF power and the second RF power having the first frequency are individually supplied at a plurality of output values into the processing container is acquired. The first plasma generation condition is specified on the basis of the output values of the first RF power and the second RF power corresponding to the data in which the numerical value for the CF active species is higher than the other data, and the bias potential is zero among the data of the active species and bias potential. Further, the second plasma generation condition is specified on the basis of the output values of the first RF power and the second RF power corresponding to the data in which the numerical value for the CF active species is lower than the other data, and the bias potential is higher than a predetermined value among the data of the active species and bias potential. As a result, more effective plasma generation conditions can be specified.

According to this embodiment, the controller 1b executes a step a) of supplying a process gas containing fluorocarbon and a rare gas to the processing container in which a placing pedestal for placing a processing target object including the first region made of silicon oxide is arranged. The controller 1b executes a step b) of generating the first plasma of the process gas by supplying the first RF power having the first frequency into the processing container. The controller 1b executes a step c) of generating the second plasma of the process gas by supplying the second RF power having the second frequency lower than the first frequency into the processing container and drawing the ions contained in the second plasma to the processing target object. In the b) and the c), the supply and stop of the supply of the first RF power and the second RF power are controlled independently of each other for each predetermined frequency, and the first RF power and the second RF power are exclusively supplied. As a result, the etching can be performed at a higher speed and a higher selection ratio than the gas switching method.

Although various exemplary embodiments have been described above, various additions, omissions, substitutions, and changes may be made without being limited to the above-described exemplary embodiments. Further, it is also possible to combine elements in different embodiments to form other embodiments.

In the above-described embodiment, the plasma processing apparatus 1a which performs processing such as etching on the substrate W by using capacitively coupled plasma as a plasma source has been described as an example, but the disclosed technology is not limited to this. The plasma source is not limited to capacitively coupled plasma as long as the apparatus is an apparatus which processes the substrate W by using plasma, and any plasma source such as inductively coupled plasma, microwave plasma, or magnetron plasma may be used.

According to the present disclosure, etching can be performed at a higher speed and a higher selection ratio than the gas switching method.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A substrate processing apparatus, comprising:
a processing chamber;
a support in the processing chamber and on which a processing target object including a first region made of silicon oxide is placed; and
a control circuit, wherein
a) the control circuit is configured to cause the substrate processing apparatus to supply a process gas containing fluorocarbon and a rare gas to the processing chamber,
b) the control circuit is configured to cause the substrate processing apparatus to plasma-process the processing target object by a first plasma of the process gas generated under a first plasma generation condition,
c) the control circuit is configured to cause the substrate processing apparatus to plasma-process the processing target object in which a bias potential is generated on the processing target object by a second plasma of the process gas generated under a second plasma generation condition different from the first plasma generation condition, and
d) the control circuit is configured to cause the substrate processing apparatus to repeat the b) and the c).

2. The substrate processing apparatus according to claim 1, wherein the support includes a chuck to receive the processing target object and a lower electrode under the chuck.

3. The substrate processing apparatus according to claim 2, further comprising an upper electrode spaced apart from the chuck, the upper electrode being on an opposite side of the chuck than the lower electrode.

4. The substrate processing apparatus according to claim 3, wherein the upper electrode receives process gas and includes gas outlets to supply the process gas the processing chamber in a).

5. The substrate processing apparatus according to claim 3, wherein the first plasma generation condition in b) includes supplying a first RF power having a first frequency to the upper electrode.

6. The substrate processing apparatus according to claim 5, wherein the first plasma generation condition in b) supplying no power to the lower electrode.

7. The substrate processing apparatus according to claim 5, wherein the second plasma generation condition in c) includes supplying the bias potential having second frequency, less than the first frequency, to the lower electrode.

8. The substrate processing apparatus according to claim 5, wherein the second plasma generation condition in c) includes supplying no power to the upper electrode.

9. The substrate processing apparatus according to claim 3, wherein the second plasma generation condition in c) includes supplying the bias potential to the lower electrode.

10. The substrate processing apparatus according to claim 9, wherein the second plasma generation condition in c) further includes supplying no power to the upper electrode.

11. The substrate processing apparatus according to claim 1, further comprising e) the control circuit is configured to cause the substrate processing apparatus to stop the plasma-process under the first plasma generation condition and delay generation of the bias potential in c).

12. The substrate processing apparatus according to claim 1, wherein the control circuit is configured to cause the substrate processing apparatus to repeat the b), the e), and the c), in that order.

13. A substrate processing apparatus, comprising:
a processing chamber;
a support in the processing chamber and on which a processing target object including a first region made of silicon oxide is placed; and
a control circuit, wherein the control circuit is configured to
a) supply a process gas containing fluorocarbon and a rare gas to a processing container in which a placing pedestal for placing a processing target object including a first region made of silicon oxide is arranged;
b) supply a first RF power having a first frequency range into the processing container from a first power supply to generate a first plasma of the process gas from a first power supply; and
c) supply a second RF power having a second frequency range lower than the first frequency range into the processing container from a second power supply, separate from the first power supply, to generate a second plasma of the process gas, to draw ions contained in the second plasma to the processing target object, wherein the first frequency range and the second frequency range do not overlap,
in the b) and the c), supply and stop of the supply of the first RF power having the first frequency range and the second RF power having the second frequency range are controlled independently of each other for each predetermined frequency, and
apply only the first RF power at the first frequency range from the first power supply during b) and applying only the second RF power at the second frequency range from the second power supply during c).

14. The substrate processing apparatus according to claim 13, wherein the support includes a chuck to receive the processing target object and a lower electrode under the chuck and further comprising an upper electrode spaced apart from the chuck, the upper electrode being on an opposite side of the chuck, wherein the first RF power is supplied only to the upper electrode and the second RF power is supplied only to the lower electrode.

15. The substrate processing apparatus according to claim 13, wherein the control circuit is further configured to d) stop supply of the first RF power and delay the supply of the second RF power.

16. The substrate processing apparatus according to claim 15, wherein the control circuit is configured to cause the substrate processing apparatus to repeat the b), the e), and the c), in that order.

17. The substrate processing apparatus according to claim 16, wherein the control circuit is configured to delay the supply of the second RF power by between 12% and 25% of one cycle.

18. A substrate processing apparatus, comprising:
a control circuit, wherein the control circuit is configured to
a) supply a process gas containing fluorocarbon and a rare gas to a processing chamber in which a support for placing a processing target object including a first region made of silicon oxide is arranged;
b) plasma-process the processing target object by a first plasma of the process gas generated under a first plasma generation condition;
c) plasma-process the processing target object in which a bias potential is generated on the processing target object by a second plasma of the process gas generated under a second plasma generation condition different from the first plasma generation condition; and
d) repeating the b) and the c).

19. The substrate processing apparatus according to claim 18, wherein the support includes a chuck to receive the processing target object and a lower electrode under the chuck and the processing chamber includes an upper electrode spaced apart from the chuck, the upper electrode being on an opposite side of the chuck, wherein the first plasma generation condition includes supplying power only to the upper electrode and the second plasma generation condition includes supplying power only to the lower electrode.

20. The substrate processing apparatus according to claim 19, wherein the control circuit is further configured to e) stop supply of power to the upper electrode and delay the supply of power to the lower electrode.
